(19) United States
(12) Patent Application Publication
(10) Pub. No.: US 2026/0307980 A1
(43) Pub. Date: Oct. 8, 2026

(54) MICROELECTROMECHANICAL SYSTEMS (MEMS) ACTUATOR WITH MAGNETIC LATCHING AND METHODS FOR MANUFACTURING AND USING THE SAME

(71) Applicant: Atomic Machines, Inc., Emeryville, CA (US)

(72) Inventors: William A. Boettcher, Albany, CA (US); Jeffrey A. Holden, San Rafael, CA (US); Klaus R. Zietlow, Piedmont, CA (US)

(21) Appl. No.: 19/717,366

(22) Filed: Jun. 23, 2026

Related U.S. Application Data
(62) Division of application No. 18/631,659, filed on Apr. 10, 2024.
(60) Provisional application No. 63/497,361, filed on Apr. 20, 2023.

(51) Int. Cl. B81B 3/00; B81C 1/00; H01F 7/16

(52) U.S. Cl. CPC B81B 3/0091; B81C 1/00706; H01F 7/1615; B81B 2201/038; B81B 2203/019; B81B 2203/053; H01F 7/132; H01F 7/134; H01F 7/16

(57) ABSTRACT

Introduced here is an electromechanical actuator that includes a stator assembly with a chamber partially defined therethrough along a central longitudinal axis and a plunger assembly that is situated in the chamber and, in operation, moves along the central longitudinal axis between different positions. The stator assembly can include a pair of contacts that have an opening therebetween and a trinity of ferromagnetic layers with coils situated therebetween. The plunger assembly can include a magnet. When current is applied to the coils, the trinity of ferromagnetic layers become magnetically polarized, thereby dictating the motion of the plunger assembly by magnetically attracting or repelling the magnet included in the plunger assembly. The plunger assembly may be stabilized by a flexure flexibly connecting the stator assembly and plunger assembly.

### CROSS-REFERENCE TO RELATED APPLICATIONS

This application is a divisional of U.S. application Ser. No. 18/631,659, filed Apr. 10, 2024, for MICROELECTROMECHANICAL SYSTEMS (MEMS) ACTUATOR WITH MAGNETIC LATCHING AND METHODS FOR MANUFACTURING AND USING THE SAME, which claims priority to U.S. Provisional Application No. 63/497,361, filed on Apr. 20, 2023, for MICROELECTROMECHANICAL SYSTEMS (MEMS) ACTUATOR WITH MAGNETIC LATCHING AND METHODS FOR MANUFACTURING AND USING THE SAME, which are hereby incorporated by reference, for all purposes, as if fully set forth herein.

### TECHNICAL FIELD

Various embodiments pertain to electromechanical actuators, and more specifically to actuators that are designed for applications requiring rapid movement, bistable latching, large latching force relative to size, and/or large travel, and approaches to manufacturing and using those electromechanical actuators.

### BACKGROUND

An electromechanical actuator is a device which converts an electric current to mechanical motion. A solenoid actuator is a specific type of electromechanical actuator which provides linear motion between two positions. Solenoid actuators are used in a wide variety of applications, including opening and closing electrical contacts in relays, opening and closing valves, latching and unlatching doors or hatches. Solenoid actuators are constructed using a coil of wire wrapped around an open cavity or ferromagnetic core. A ferromagnetic armature (also called a “plunger” or “piston”) may be located inside the coil or may be located axially at one end of the coil. Current flowing through the coil produces a magnetic field, causing the armature of the solenoid actuator to “pull in.” When current flow is stopped, a spring causes the armature to return to its un-energized position. Some solenoid actuators are bistable (or “latching”). In such a solenoid actuator, the plunger will be retained at either end of travel by means of a magnet or mechanical constraint. In the case of a bistable solenoid actuator, the current through the coil can be delivered in either direction to send the plunger from one end of the solenoid actuator to the other.

### BRIEF DESCRIPTION OF THE DRAWINGS

This patent or application contains at least one drawing executed in color. Copies of this patent or application publication with color drawings will be provided by the Office upon request and payment of the necessary fee.

FIG. 1 includes a diagrammatic illustration of a solenoid or actuator having a traditional electromagnetic form.

FIG. 2A includes a cross-sectional view of the various layers of an actuator in accordance with various embodiments of the present disclosure.

FIGS. 2B-C illustrate how the various layers of the electromechanical actuator shown in FIG. 2A generally correspond to one of two “stacks,” namely, a static stack (also called a “stator assembly”) or an actuatable stack (also called a “rotor assembly” or “plunger assembly”).

FIG. 3 includes a simplified diagrammatic illustration of the latching behavior of an electromechanical actuator caused by magnetic circuits in the “open position” and “closed position.”

FIG. 4 includes a diagrammatic illustration showing how passing current through coils will result in an approximately constant magnetic force being applied to the plunger.

FIGS. 5A-E illustrate the magnetic flux in a plunger assembly that is moving from the first position to the second position and then returning to the first position.

FIG. 6 includes a perspective, section view that illustrates how a flexure connected to a plunger assembly can constrain movement of the plunger assembly with respect to a stator assembly.

FIG. 7 includes a section view diagrammatic illustration of the plunger assembly, contact assembly, and stator assembly.

FIG. 8 includes a section view of the electromechanical actuator, as well as a diagrammatic illustration of a possible assembly sequence.

FIG. 9 includes a high-level diagram of a process for fabricating an electromechanical actuator.

Embodiments are illustrated by way of example and not limitation in the drawings. While the drawings depict various embodiments for the purpose of illustration, those skilled in the art will recognize that alternative embodiments may be employed without departing from the principles of the technology. Accordingly, while specific embodiments are shown in the drawings, the technology is amenable to various modifications.

### DETAILED DESCRIPTION

Electromechanical actuators have historically been used in many contexts. Many devices requiring electrically controlled motion can be driven by an electromechanical actuator. Examples of such devices include valves, haptic feedback devices, and electromechanical relays. Low-power devices—like microprocessors—can drive such actuators to activate switches (relays) to control electrical loads beyond their direct drive capability. Electromechanical actuators can also be used to drive valves, optical elements such as mirrors or lenses, mechanical or electrical tuning elements, fluid pressure modulators, or pumps, as well as many other useful loads in other applications.

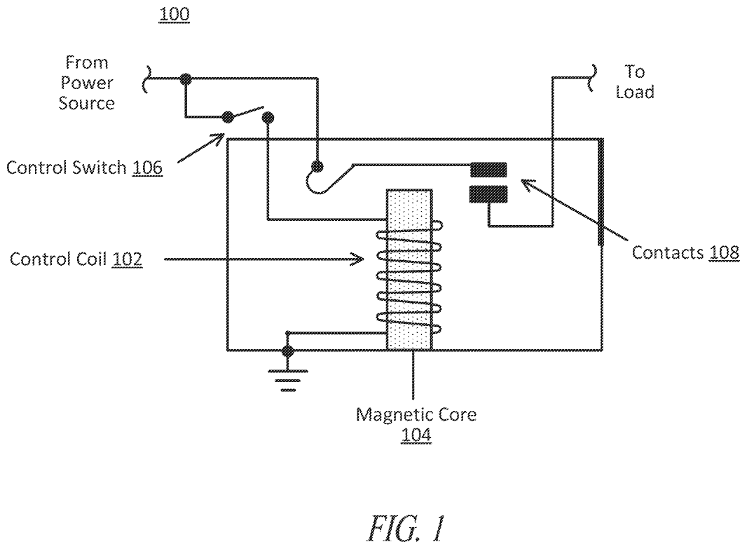

FIG. 1 includes a diagrammatic illustration of a solenoid or actuator having a traditional electromagnetic form. The traditional electromagnet form includes a control coil 102 that is wrapped around a ferromagnetic core 104. Application of an electrical current through control coil 102 creates a magnetic field with general orientation parallel to the axis of the coil 102. This magnetic field attracts the upper of the two contacts 108. The upper contact moves downward until it touches the lower contact 108. This closes the switch allowing current to flow from the power source to the load. When the current through the control coil 102 is interrupted by opening Control Switch 106, the upper contact 108 is restored to its neutral open position by spring force.

Typically, conventional electromechanical actuators are at least several centimeters in both length and width. Their construction requires coils of windings, which must be formed using bobbin-winding machinery. The winding of a coil adds to the complexity, and therefore the cost, of producing such an actuator. In contrast, the electromechanical actuators introduced here allow for the use of planar circuitry, reducing the complexity of forming the coils, and allowing the resulting device to be much smaller, with dimensions of 1 millimeter (mm)×6 mm×6 mm or less. This allows the resulting device to be used in applications requiring a small size.

Traditional solenoid actuators are typically not latched in position at the end of the stroke, and even in implementations where latching is possible, latching is typically achieved using a mechanical means. The mechanical latch adds a moving part to the design which increases its cost and reduces reliability. The electromechanical actuator introduced here provides magnetic latching at each end of the stroke as a function of its design, and with no additional components required. The magnetic latching is completely passive and requires no external energy to retain the plunger at either end of the stroke.

### Terminology

Brief definitions of terms, abbreviations, and phrases used throughout the application are given below.

References in this description to “an embodiment” or “some embodiments” means that the feature being described is included in at least one embodiment of the technology. Occurrences of such phrases do not necessarily refer to the same embodiment, nor are they necessarily referring to alternative embodiments that are mutually exclusive of one another.

The terms “comprise,” “comprising,” and “comprised of” are to be construed in an inclusive sense rather than an exclusive or exhaustive sense (i.e., in the sense of “including but not limited to”). The term “based on” is also to be construed in an inclusive sense rather than an exclusive or exhaustive sense. Accordingly, the term “based on” is intended to mean “based at least in part on” unless otherwise noted.

The terms “connected,” “coupled,” and any variants thereof are intended to include any connection or coupling between two or more elements, either direct or indirect. The connection or coupling can be physical, logical, or a combination thereof. For example, objects may be electrically or communicatively connected to one another despite not sharing a physical connection.

### Overview of Electromechanical Actuator

At a high level, the electromechanical actuators described herein are laminated devices, generally manufactured by cutting thin sheets of material and then bonding those thin sheets together in stacks as further discussed below. With successive cutting/bonding iterations, the structures that collectively comprise an electromechanical actuator can be placed in-plane with each other in nearly any arbitrary configuration.

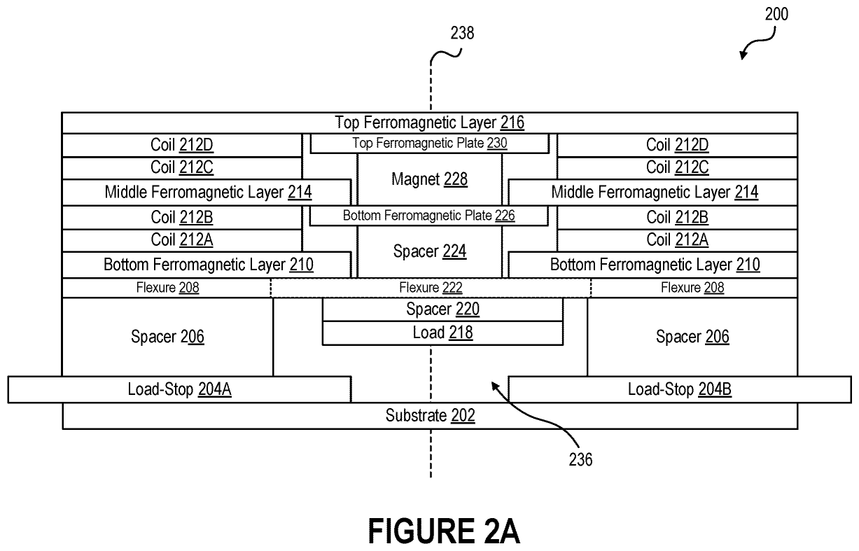

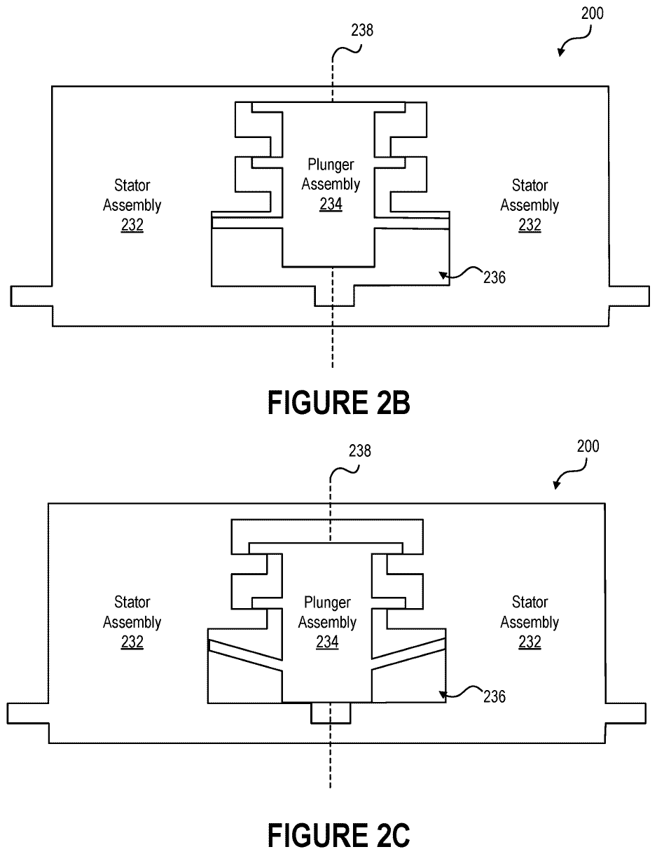

FIG. 2A includes a cross-sectional view of the various layers of an electromechanical actuator 200 in accordance with various embodiments of the present disclosure. Meanwhile, FIGS. 2B-C illustrate how the various layers of the electromechanical actuator 200 generally correspond to one of two “stacks,” namely, a static stack 232 (also called a “static assembly,” “stator assembly” or simply “stator”) or an actuatable stack 234 (also called an “actuatable assembly,” “rotor assembly,” “plunger assembly,” or “plunger”). As further discussed below, the plunger assembly 234 can be vertically displaced within the stator assembly 232 in order to controllably move a load 218.

Referring again to FIG. 2A, the stator assembly 232 is representative of a collection of layers that have a chamber 236 partially defined therethrough along a central longitudinal axis 238. The central longitudinal axis 238 may roughly bisect the width of the electromechanical actuator 200. A substrate 202 can be the bottommost layer of the stator assembly 232. The substrate 202 may be a small block of insulating material on which a functional component—for example a relay or valve—is fabricated to complete an electromechanical device. The insulating material could be ceramic or glass, for example. Insulation may not always be necessary (e.g., insulation may be helpful if the electromechanical actuator 200 forms part of an electrical switch). As such, the substrate 202 may alternatively be comprised of a non-insulating material on which the functional component is fabricated to complete an electromechanical device. Some embodiments may not include a substrate 202 at all, in which case the load-stops 204A-B may be the bottommost layers of the electromechanical actuator 200.

In terms of “footprint,” it is generally desirable to make the electromechanical actuator 200 as small as possible within the limits set by current density. Cost and magnetic performance tend to scale favorably as size decreases. For example, the actuation force may be proportional to the square root of the moving magnet mass of the electromechanical actuator 200 and the square root of power consumed. In general, the substrate 202 may be less than four mm thick (and preferably less than 3 mm thick). The thickness of the substrate 202 may be fundamental to the operation of the electromechanical device, and therefore may not depend heavily on the intended application of the electromechanical actuator 200. The shape, length, and width of the substrate 202 may vary depending on the intended application of the electromechanical device 200. However, in some embodiments, the length may not exceed 10 mm, 20 mm, 25 mm, or 50 mm, and the width may not exceed 10 mm, 20 mm, 25 mm, or 50 mm. Accordingly, the surface area of the substrate 202 may be less than 100 mm² (i.e., 10 mm×10 mm). 400 mm² (i.e., 20 mm×20 mm), 625 mm² (i.e., 25 mm×25 mm), or 2,500 mm² (i.e., 50 mm×50 mm). In other embodiments, the length and/or width may exceed 50 mm, and therefore the surface area of the substrate 202 may exceed 625 mm², as there are no fundamental size constraints on the electromechanical actuator 200.

The stator assembly 232 and plunger assembly 234 can be connected to one another by one or more flexures that are intended to constrain lateral motion of the plunger assembly 234 as it moves vertically within the chamber of the stator assembly 232, as well as to control, inhibit, or limit tilting. Specifically, a flexure may be designed to provide a desired axial force when the plunger assembly 234 is latched, such that the axial force provided by the flexure counters the latching force to enable and support faster movement of the plunger assembly 234 when current is applied to the coils in the stator assembly 232. In some embodiments, multiple flexures are used to constrain torsional movement (“tilting”) and horizontal movement of the plunger assembly 234, while in other embodiments, a single flexure is used to constrain horizontal movement of the plunger assembly 234 with a generally lesser degree of torsional constraint.

The flexures 208, 222 are compliant mechanisms that require relatively little force to deflect in the direction of actuation (i.e., along the central longitudinal axis 238) but require much larger amounts of force to deflect in any other direction. As further discussed below, the flexures 208, 222 may be representative of different parts of the same flexure, which flexibly connects the stator assembly 232 and plunger assembly 234. This property largely constrains the plunger assembly 234 to taking the same path through the center of the stator assembly 232 during every actuation. Moreover, this property largely or entirely eliminates friction between the stator assembly 232 and plunger assembly 234 and limits rotation of the plunger assembly 234 inside the chamber 236 of the stator assembly 232. In the embodiment shown in FIG. 2A, the flexures 208, 222—again, which may be representative of different components of a single flexure—can apply a “bias force” to the plunger assembly 234 in either direction, which allows for higher initial actuation force (and consequently faster displacement) during actuation. Generally, the flexures 208, 222 are comprised of metal, metal alloy, or polymer.

As shown in FIG. 2A, the stator assembly can include a series of ferromagnetic layers with coils situated therebetween. During actuation, current is applied to the coils to magnetically polarize the series of ferromagnetic layers as further discussed below. In the embodiment shown in FIG. 2A, the stator assembly 232 includes a trinity of ferromagnetic layers, namely, a first ferromagnetic layer 210 (also called the “bottom ferromagnetic layer”), a second ferromagnetic layer 214 (also called the “middle ferromagnetic layer”), and a third ferromagnetic layer 216 (also called the “top ferromagnetic layer”). Generally, the bottom and middle ferromagnetic layers 210, 214 extend circumferentially around the chamber 236, and therefore may have an annular form. Meanwhile, the top ferromagnetic layer 216 may extend across the entire width of the stator assembly 232, such that its bottom surface defines the upper end of the chamber 236. While the top ferromagnetic layer 216 shown in FIG. 2A has a disk form, the top ferromagnetic layer 216 could have an annular form similar to the middle and bottom ferromagnetic layers 214, 210. In such embodiments, the aperture in the top ferromagnetic layer 216 may allow for observation and/or metrology of the motion of the plunger assembly 234, and/or the connection of an additional load on the top of the plunger. Note that the aperture may be sized to ensure its diameter is smaller than the diameter of the top ferromagnetic plate 230, so as to ensure that the plunger assembly 234 remains fully constrained within the chamber of the stator assembly 232.

The bottom, middle, and top ferromagnetic layers 210, 214, 216 are generally only as thick as necessary to prevent magnetic saturation while the plunger assembly 234 is actuating within the chamber 236 of the stator assembly 232. Generally, the thickness of the bottom, middle, and top ferromagnetic layers 210, 214, 216 is no more than 0.4 mm (and preferably 0.3 mm). Most of the other layers included in the stator assembly 232 are less constrained, and therefore may be determined based on the intended application of the electromechanical device 200. For example, the thickness of the “coil stacks” may vary depending on the number of coils, and the thickness of the spacer 206 may depend on the plunger assembly 234, as a bottom portion of the plunger assembly 234 must be able to move—in the chamber 236—between the top surface of the load-stops 204A-B and the bottom surface of the bottom ferromagnetic layer 210. The load-stops 204A-B are the surfaces with which the load makes contact at the ‘closed’ end of its stroke. The load-stops 204A-B may serve different purposes depending on the device in which the actuator is incorporated. In a relay, for example, the load stops 204A-B may be conductive elements that are shorted together by the load 218 when the load 218 is in the closed position. In a MEMS valve, the load stops 204A-B (or a singular load stop) may be a valve seat. In this situation, the load 218 would become the valve itself, and would seal against the valve seat in the closed position. As such, the load-stops 204A-B are shown in FIG. 2A to illustrate surfaces with which the plunger makes contact. Note that various intermediary layers (e.g., flexures and spacers) have not been shown to simplify FIG. 2A. These various intermediary layers generally have thicknesses between 25-375 micrometers (μm) and widths of 1.5-6 mm. Generally, all of the layers shown in FIG. 2A have thicknesses of 25-375 μm and widths of 1.5-6 mm, though the dimensions may depend on the intended application of the electromechanical actuator 200.

One or more coils can be situated between each set of ferromagnetic layers. In the embodiment shown in FIG. 2A, for example, a first plurality of coils is situated between the bottom and middle ferromagnetic layers 210, 214, while a second plurality of coils is situated between the middle and top ferromagnetic layers 214, 216. Such a design results in the bottom ferromagnetic layer 210 being located adjacent to the load-stops 204A-B, the first plurality of coils being located adjacent to the bottom ferromagnetic layer 210, the middle ferromagnetic layer 214 being located adjacent to the first plurality of coils, the second plurality of coils being located adjacent to the middle ferromagnetic layer 214, and the top ferromagnetic layer 216 being located adjacent to the second plurality of coils. Note that the term “adjacent,” as used herein, may be used to generally refer to the spatial relationship between two components. A first component may be “adjacent” to a second component without the respective sides adjoining one another. Therefore, there may be one or more intermediary components between components that are “adjacent” to one another. Conversely, the term “directly adjacent” is generally used to refer to components that adjoin one another without any intermediary components therebetween, with the exception of adhesives or other materials as may be required to bond them.

In the embodiment shown in FIG. 2A, the first plurality of coils includes a pair of coils 212A-B, while the second plurality of coils also includes a pair of coils 212C-D. While the first and second pluralities of coils include the same number of coils in FIG. 2A, the first and second plurality of coils could include different numbers of coils. For example, a single coil could be situated between a pair of ferromagnetic layers. The number of coils that is required may depend on the forces required to actuate given the latching force, the desired drive voltage and current, and the acceleration required to meet a desired opening time requirement and/or closing time requirement.

In operation, current is applied to the coils 212A-D as further discussed below. When this happens, the coils 212A-D produce magnetic fields in opposite directions, such that the bottom, middle, and top ferromagnetic layers 210, 214, 216 in the stator assembly 232 have inner poles in a north-south-north (“N-S-N”) configuration or a south-north-south (“S-N-S”) configuration from top to bottom depending on the direction of the current. Note that the term “inner pole” is used to describe the radial end of each ferromagnetic layer that is located nearest the plunger assembly 234. Because the plunger assembly 234 has two fixed poles (i.e., either a north-south configuration or south-north configuration, which is defined during manufacture of the plunger assembly 234 by the orientation of permanent magnet 228), all adjacent poles between the stator assembly 232 and plunger assembly 234 will push or pull in the same direction, and reversing the direction of the current will reverse the direction in which the stator assembly 232 and plunger assembly 234 are pushed or pulled.

The plunger assembly 234 is representative of another collection of layers that is situated in the chamber 236 of the stator assembly 232 and, in operation, moves along the central longitudinal axis 238 between the first and second positions.

As mentioned above, the stator assembly 232 and plunger assembly 234 can be connected to one another by one or more flexures. In the embodiment shown in FIG. 2A, the diagram features 208 and 222 are representative of different regions of a single flexure layer. Thus, the inner flexure region 222 may be directly connected to the outer flexure regions 208, and while the inner flexure region 222 may move vertically with the plunger assembly 234 by the elastic deformation of the flexure layer, the outer flexure regions 208 may remain static—embedded in the layers of the stator assembly 232—despite being connected to the inner flexure region 222. The flexure may be designed to permit vertical displacement in the range of 0 and 25 microns, between 25 and 100 microns, between 100 and 150 microns, between 150 and 200 microns, between 200 and 250 microns, or greater than 250 microns. The flexure can have various forms. For example, the flexure could be in the form of a disk with a circular annulus, or the flexure could have a central circular part and a hexagonal annulus, connected by three interconnecting segments (also called “arms”) that flex. In FIG. 2A, the outer flexure region 208 is the hexagonal annulus while the inner flexure region 222 is the center circular part. Thus, the outer and inner flexure regions 208 and 222 are part of the same layer. In embodiments where the electromechanical device 200 includes multiple flexures, flexures could be arranged at different heights along the “stack.” Having more than one flexure would provide better (i.e., stiffer) angular control of the motion of the plunger assembly 234, preventing the plunger assembly 234 from “tipping” as it moves vertically. Additional flexures may also allow stresses to be distributed between them, enabling longer fatigue lives and/or additional material options.

A spacer 224 may be situated along the top surface of the flexure 222, such that when the plunger assembly 234 is located in the first position, a bottom portion of the spacer 224 is horizontally aligned with the bottom ferromagnetic layer 210 of the stator assembly 232, as shown in FIG. 2A. When the plunger assembly 234 is located in the second position, a top portion of the spacer 224 may be horizontally aligned with the bottom ferromagnetic layer 210 of the stator assembly 232. At a high level, the thickness of the spacer 224 may be selected to accommodate controlled movement of the plunger assembly 234.

A plunger element (or simply “plunger”) can be situated along the top surface of the spacer 224. The plunger element can include a permanent magnet 228 with ferromagnetic plates adhered, laminated, or otherwise secured along its top and bottom poles. Specifically, a bottom ferromagnetic plate 226 may be connected along the bottom pole of the permanent magnet 228, and a top ferromagnetic plate 230 may be connected along the top pole of the permanent magnet 228. As shown in FIG. 2A, the top and bottom ferromagnetic plates 226, 230 can sit between the ferromagnetic layers in the stator assembly 232. Specifically, the bottom ferromagnetic plate 226 may be situated between the bottom and middle ferromagnetic layers 210, 214, while the top ferromagnetic plate 230 may be situated between the middle and top ferromagnetic layers 214, 216. In operation, the top and bottom ferromagnetic plates 226, 230 can couple the permanent magnet 228 to the bottom, middle, and top ferromagnetic layers 210, 214, 216 by providing a low-reluctance path for magnetic fields generated by the coils 212A-D to follow.

Accordingly, the plunger assembly 234 may include (i) a load 218 which is a component driven by the actuator which performs some function when moved, (ii) a flexure 222 for controlling vertical movement along the central longitudinal axis 238, (iii) a spacer 224, and (iv) a permanent magnet 228 with top and bottom ferromagnetic plates 230, 226 secured along its poles. The top ferromagnetic plate 230 may be situated between the top and middle ferromagnetic layers 216, 214 of the stator assembly 232, while the bottom ferromagnetic plate 226 may be situated between the middle and bottom ferromagnetic layers 214, 210.

Thickness of the permanent magnet 228 is generally maximized within the constraints set by the surrounding layers and application of the electromechanical actuator 200, both mechanically and magnetically. For example, the magnet thickness may be selected so as not to exceed the saturation flux density of ferromagnetic plates 226 and 230. Similarly, the magnet thickness may also be selected such that the total magnetic flux is sufficient to produce adequate latching force for the intended application of a particular embodiment. Mechanical constraints on magnet thickness may include that vertical distance between the top surface of the bottom ferromagnetic plate 226 and the bottom surface of the top ferromagnetic plate 230 does not exceed the difference between the thickness of the middle ferromagnetic layer 214 and the intended length of the stroke. The thickness of the permanent magnet 228 may typically be sized such that the top ferromagnetic plate 230 makes contact with the top ferromagnetic layer 216 at the same time as the bottom ferromagnetic plate 226 touches the middle ferromagnetic layer 214 at the top of the stroke, and the top ferromagnetic plate 230 touches the middle ferromagnetic layer 214 at the same time as the bottom ferromagnetic plate 226 touches the bottom ferromagnetic layer 210 at the bottom of the stroke (i.e. the gaps are equal on both sides). This may tend to maximize magnetic forces—both in latching and actuation—by minimizing the gaps in the magnetic circuit at either end of the stroke.

Similar to the stator assembly 232, the dimensions of the layers in the plunger assembly 234 are generally not constrained, and therefore may be determined based on the intended application of the electromechanical actuator 200. However, the permanent magnet 228, bottom ferromagnetic plate 226, and top ferromagnetic plate 230 may be designed while taking into account the stator assembly 232. For example, the permanent magnet 228, bottom ferromagnetic plate 226, and top ferromagnetic plate 230 should be designed such that (i) the top ferromagnetic plate 230 is able to move within a gap between the top surface of the middle ferromagnetic layer 214 and the bottom surface of the top ferromagnetic layer 216 and (ii) the bottom ferromagnetic plate 226 is able to move within a gap between the top surface of the bottom ferromagnetic layer 210 and the bottom surface of the middle ferromagnetic layer 214.

As can be seen in FIGS. 2A-C, the chamber 236 may not be purely cylindrical. Instead, the layers of the stator assembly 232 and/or plunger assembly 234 may be sized and arranged such that the chamber 236 has structural features along its longitudinal sides that allow for improved control of the plunger assembly 234. Consider, for example, the embodiment shown in FIG. 2A. In this embodiment, the top ferromagnetic layer 216 extends across the entire perimeter of the stator assembly 232. Meanwhile, the middle and bottom ferromagnetic layers 214, 210 have the forms of annular cylinders (also called “coaxial cylinders”), where the central aperture corresponds to the chamber 236. These annular cylinders are defined by an inner radius that stretches from the central longitudinal axis 238 to the inner perimeter and an outer radius that stretches from the central longitudinal axis 238 to the outer perimeter. Similarly, each “coil stack” may be in the form of an annular cylinder. However, the inner radiuses of the “coil stacks” may not be the same as the inner radiuses of the middle and bottom ferromagnetic layers 214, 210. When the inner radiuses of the “coil stacks” are larger than the inner radiuses of the middle and bottom ferromagnetic layers 214, 210, structural features—commonly called “notches” or “shelves”—are formed, and these structural features can accommodate the top and bottom ferromagnetic plates 230, 226 as discussed above.

### Overview of Principles of Operation

As mentioned above, the electromechanical actuator 200 can be driven by applying fixed pulses of current through the coils 212A-D.

To move the plunger assembly 234 from the first position to the second position, current is applied to the coils 212A-D such that the current flows in a first direction. When the plunger assembly 234 moves from the first position to the second position, downward movement may be impeded by any of (i) the mechanical resistance of the flexures 208, 222, (ii) the top ferromagnetic plate 230 contacting the top surface of the middle ferromagnetic layer 214, (iii) the bottom ferromagnetic plate 226 contacting the top surface of the bottom ferromagnetic layer 210, or (iv) the load 218 contacting the component at the end of its stroke.

To move the plunger assembly 234 from the second position to the first position, current is applied to the coils 212A-D such that the current flows in a second direction opposite the first direction. When the plunger assembly 234 moves from the second position to the first position, upward movement may be impeded by any of (i) the mechanical resistance of the outer and inner flexure regions 208, 222, (ii) the top ferromagnetic plate 230 contacting the bottom surface of the top ferromagnetic layer 216, or (iii) the bottom ferromagnetic plate 226 contacting the bottom surface of the middle ferromagnetic layer 214. Thus, upward movement may be impeded by the flexure reaching a limit of extension such that its restoring force prevents further axial motion, or upward movement may be impeded by the top ferromagnetic layer 230 or middle ferromagnetic layer acting as a physical barrier.

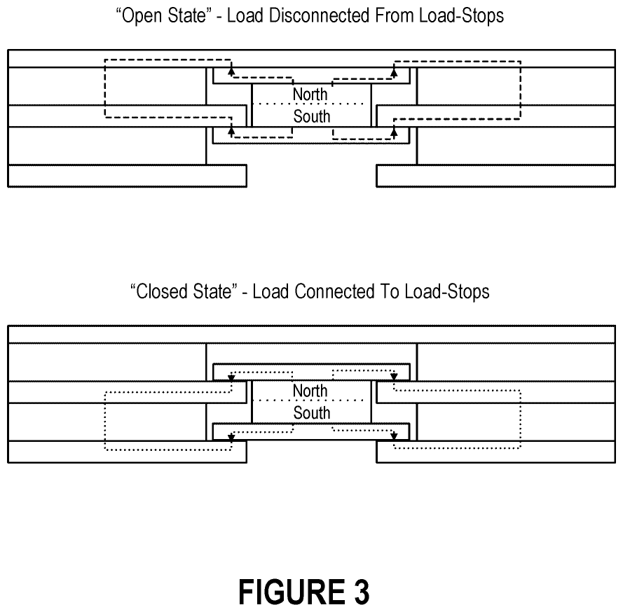

Accordingly, to actuate the plunger assembly 234, a fixed pulse of current obtained from a power source (not shown) can be applied to the coils 212A-D of the stator assembly 232, as such action magnetically polarizes the top, middle, and bottom ferromagnetic layers 216, 214, 210. A positive current may cause the plunger assembly 234 to move into the first position, thereby moving the load 218 to the “open” position. Conversely, a negative current may cause the actuator assembly 234 to move into the second position, thereby moving the load 218 to the “closed” position. FIG. 3 includes a simplified diagrammatic illustration of the latching behavior of an electromechanical actuator caused by magnetic circuits in the “open position” and “closed position.” In FIG. 3, the dashed lines indicate magnetic flux in one magnetic circuit while the dotted line indicate magnetic flux in another magnetic circuit. Magnetic flux in one direction—indicated using the dashed line—causes the electromechanical actuator to be “opened,” while magnetic flux in the opposite direction—indicated using the dotted line—causes the electromechanical actuator to be “closed.” Note that in FIG. 3, a portion of the plunger assembly is shown.

Note that while the load 218 may be described as being in the “open” position or “closed” position, those skilled in the art will recognize that these positions may simply be opposing end positions. Accordingly, the “open” position could also be called the “first end position” or simply “first position” while the “closed” position could also be called the “second end position” or simply “second position.”

### A. Magnetic Latching

An important aspect of the electromechanical actuator is its approach to actuation. Conventional electromechanical actuators may require that current be continuously applied in order to maintain a given state (e.g., the closed state). To avoid requiring that current be applied continuously for the electromechanical actuator to remain open or closed, the electromechanical actuator could instead be designed to “latch” in place whenever the state is switched. This is accomplished by designing the actuator to be magnetically bistable.

Referring to FIG. 2A, the spacing between the top, middle, and bottom ferromagnetic layers 216, 214, 210 in the stator assembly 232 can be matched to the spacing of top and bottom ferromagnetic plates 230, 226—and permanent magnet 228 and spacer 224—of the plunger assembly 234. The distance that the lines of the magnetic fields generated by the coils 212A-D pass through nonferrous material is minimized when the plunger is at its highest and lowest positions, this effect being maximized when the spacing is matched. This creates two local minima of magnetic reluctance (and therefore, potential energy) in these positions, causing the plunger to “latch” to its highest and lowest positions, magnetic “latching force” being maximized when the spacing is matched.

The size of the permanent magnet 228, thickness of the top and bottom ferromagnetic plates 230, 226, the vertical spring constant of the outer and inner flexure regions 208, 222, and distance between the highest and lowest positions can influence the latching force. To maximize the actuation speed, the net latching force (including magnetic and flexure contributions) can be minimized within the constraint set by vibration and impact resistance. Because the actuation force—which should be maximized to optimize switching speed—is largely determined based on the sum of magnetic latching force and vertical flexure force, the geometry of the flexure tends to be the easiest parameter to manipulate. Accordingly, choosing a flexure spring constant to set the “net latching force” at an appropriate value is typically preferred over redesigning or reselecting the permanent magnet 228 or top and bottom ferromagnetic plates 230, 226, or by using a larger distance (also called the “gap size”).

### B. Magnetic Actuation

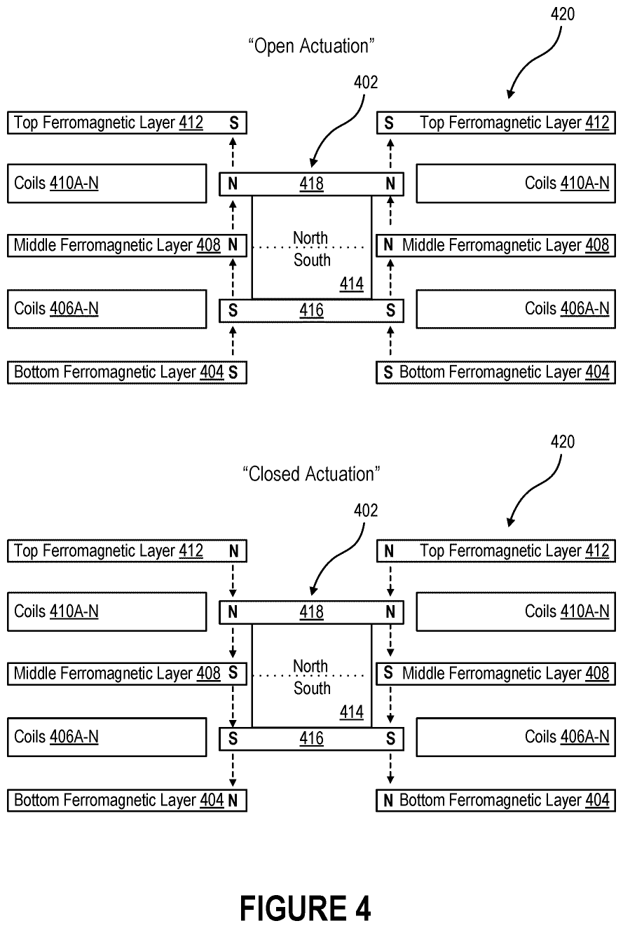

FIG. 4 includes a diagrammatic illustration showing how passing current through coils 406A-N, 410A-N will result in a constant magnetic force being applied to the plunger 402. In order to better show the magnetic force, the electromechanical actuator 400 has been “exploded” such that the various layers are separated and “expanded’ such that the various layers are not drawn to scale.

As discussed above, the stator assembly 420 can include a trinity of ferromagnetic layers with coils situated therebetween, such that (i) at least one coil is situated between the bottom and middle ferromagnetic layers 404, 408 and (ii) at least one coil is situated between the middle and top ferromagnetic layers 408, 412. For example, a plurality of coils 406A-N may be situated between the bottom and middle ferromagnetic layers 404, 408, and another plurality of coils 410A-N may be situated between the middle and top ferromagnetic layers 408, 412. The first and second pluralities of coils 406A-N, 410 A-N may include the same number of coils, or the first and second pluralities of coils 406A-N, 410 A-N may include different numbers of coils. Normally, each plurality of coils 406A-N, 410A-N includes at least two coils, though any number of coils could be situated between the bottom and middle ferromagnetic layers 404, 408 or between the middle and top ferromagnetic layers 408, 412. The thickness of each “coil stack” may depend on the size of the plunger 402, for example. The thickness of each “coil stack” tends to be proportional to the number of coils included therein.

Like FIG. 3, only the plunger 402 of the actuation assembly is shown in FIG. 4. The plunger 402 can include a permanent magnet 414 with ferromagnetic plates 416, 418 secured along its top and bottom poles. Here, for example, a bottom ferromagnetic plate 416 is connected along the bottom pole (i.e., south pole) of the permanent magnet 414, and a top ferromagnetic plate 418 is connected along the top pole (i.e., north pole) of the permanent magnet 414.

The top, middle, and bottom ferromagnetic layers 412, 408, 404 can be interleaved with the top and bottom ferromagnetic plates 416, 418 as shown in FIG. 4. The top ferromagnetic plate 418 can be situated between the top and middle ferromagnetic layers 412, 408, and the bottom ferromagnetic plate 416 can be situated between the middle and bottom ferromagnetic layers 408, 404.

As mentioned above, passing current through the coils 406A-N, 410A-N causes a constant magnetic force to be applied to the plunger 402 (and more specifically, to the top and bottom ferromagnetic plates 418, 416). This constant magnetic force is generally proportional to the current and the number of turns in the coils 406A-N, 410A-N. When this constant magnetic force overcomes the “latching force” of the plunger 402 (and more specifically, the permanent magnet 414), the plunger 402 will begin to move downward (e.g., toward the bottom ferromagnetic layer 404) or upward (e.g., toward the top ferromagnetic layer 412).

By applying a positive current to the coils 406A-N, 410A-N, movement in one direction (e.g., upward) can be achieved. Applying a negative current to the coils 406A-N, 410A-N may result in movement in the other direction (e.g., downward). For example, a positive current may cause the plunger 402 to move upward until the top ferromagnetic plate 418 contacts the bottom surface of the top ferromagnetic layer 412 and/or the bottom ferromagnetic plate 416 contacts the bottom surface of the middle ferromagnetic layer 408. When the plunger 402 is in this position, the electromechanical actuator 400 may be described as “open.” Conversely, a negative current may cause the plunger 402 to move downward until the top ferromagnetic plate 418 contacts the top surface of the middle ferromagnetic layer 408 and/or the bottom ferromagnetic plate 416 contacts the top surface of the bottom ferromagnetic layer 404. When the plunger 402 is in this position, the electromechanical actuator 400 may be described as “closed.”

Various parameters can influence this constant magnetic force, as well as the speed at which the plunger 402 is able to move between positions. These parameters include:
Thickness and composition of the top, middle, and bottom ferromagnetic layers 412, 408, 404.
   For example, thickness of the top, middle, and bottom ferromagnetic layers may be 25-325 μm.
Thickness and grade of the permanent magnet 414.
   For example, thickness of the permanent magnet 414 may be 0.2-0.5 mm.
Number of turns of the coils 406A-N, 410A-N.
Magnitude of current applied to the coils 406A-N, 410A-N.
Diameters of the coils 406A-N, 410A-N and permanent magnet 414.
Spacing between, and overlap with, the top, middle, and bottom ferromagnetic layers 412, 408, 404, as the spatial relationship impacts the direction of the magnetic field gradient.

In operation, current is applied to the coils 406A-N, 410A-N. When this happens, the coils 406A-N, 410A-N produce magnetic fields in opposite directions, so as to induce poles in the top, middle, and bottom ferromagnetic layers 412, 408, 404. Depending on the direction of the current, the inner poles of the top, middle, and bottom ferromagnetic layers 412, 408, 404 may be an N-S-N configuration or S-N-S configuration. The permanent magnet 414 has two fixed poles. Here, for example, the permanent magnet has an N-S configuration. Therefore, when the top, middle, and bottom ferromagnetic layers 412, 408, 404 are magnetically polarized, all of the inner poles of the stator assembly 420 will push or pull the plunger 402 in the same direction. Reversing the direction of the current will reverse the direction in which the inner poles of the stator assembly 420 push or pull the plunger 402. FIG. 4 illustrates how applying current to the coils 406A-N, 410A-N can induce magnetic polarization that causes magnetic forces to be applied to the plunger 402.

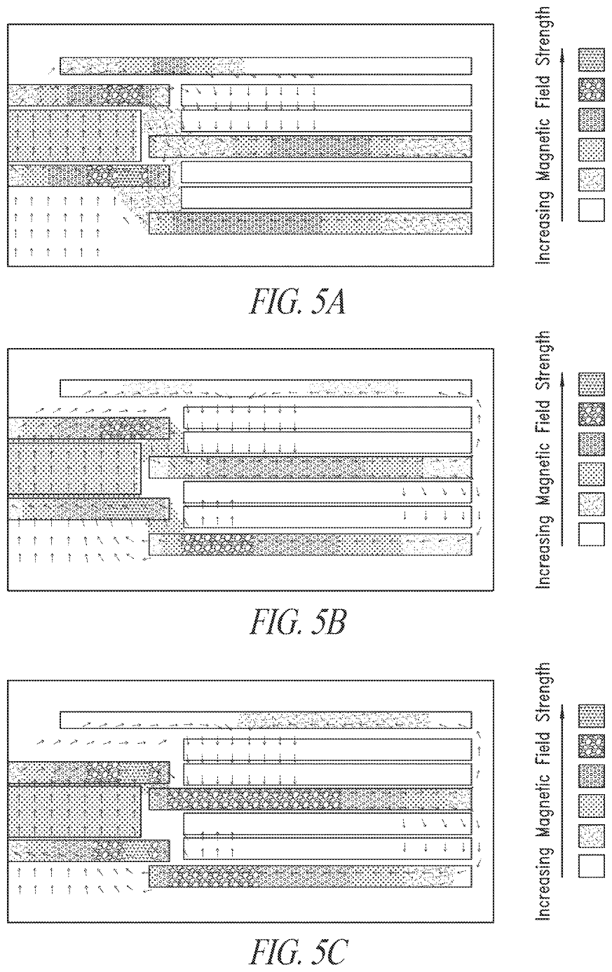

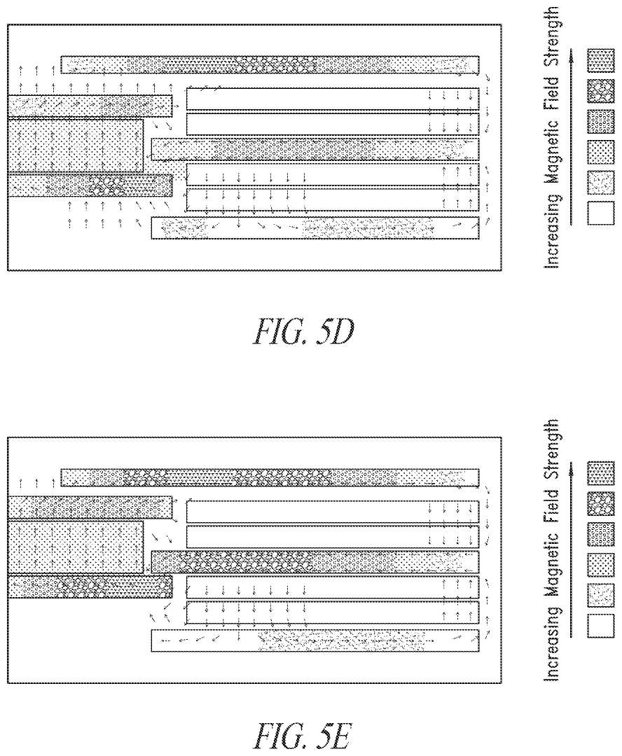

FIGS. 5A-E include visualizations that illustrate the magnetic field strength and direction as the plunger assembly is moved between the first and second positions. Specifically, FIG. 5A illustrates the plunger assembly in the first position. In order to move the plunger assembly into the second position, a fixed pulse of positive current can be applied to the coils, so as to magnetically draw the plunger assembly downward. FIG. 5B illustrates the plunger assembly as it is moving toward the second position, while FIG. 5C illustrates the plunger assembly in the second position. In order to move the plunger assembly back into the first position, a fixed pulse of negative current can be applied to the coils, so as to magnetically draw the plunger assembly upward. FIG. 5D illustrates the plunger assembly as it is moving toward the first position, while FIG. 5E illustrates the plunger assembly back in the first position.

### C. Constrained Motion and Flexures

Flexures (e.g., flexures 208, 222 of FIG. 2A) can be used to keep the plunger assembly centered within the chamber of the stator assembly, to ensure that movement is largely, if not entirely, vertical along a central longitudinal axis. Further, these flexures can inhibit or prevent friction between the various layers of the plunger assembly and stator assembly. To accomplish this, the flexures may need to have a stiffness with respect to lateral motion of at least the maximum lateral magnetic force—making worst-case assumptions for geometry within manufacturing tolerances—divided by the worst-case clearance within manufacturing tolerances.

To ensure that the load (e.g., load 218 of FIG. 2A) is able to sit flat along the top surface of the load-stops (e.g., load-stops 204A-B of FIG. 2A), the maximum lateral asymmetry in flexure force may be less than the remaining closed-side latching force after any force applied by the flexures is considered.

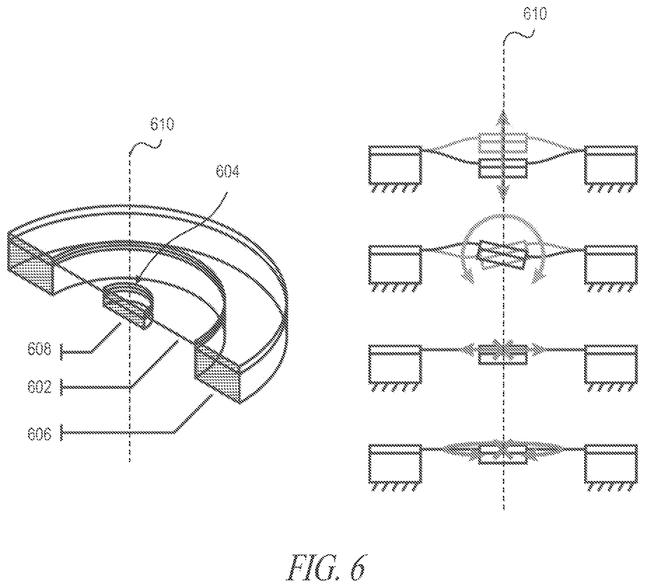

FIG. 6 includes a perspective, section view that illustrates how a flexure 602 connected to a plunger assembly 604 can restrict movement of the plunger assembly 604 with respect to a stator assembly 606. To ensure that the flexure 602 is appropriately positioned, the flexure 602 may be “sandwiched” between layers in the plunger assembly 604 and/or the stator assembly 606. For example, the flexure 602 may be interposed between ceramic layers.

For simplicity, only some components of the plunger and stator assemblies 604, 606 are shown in FIG. 6. Specifically, FIG. 6 shows how the flexure 602 can ensure that movement of the load 608 is substantially vertical or longitudinal, namely, along a longitudinal axis 610. While some degree of tilt may occur, the plunger assembly 604 will not experience any meaningful horizontal or lateral movement, nor will the plunger assembly 604 experience any meaningful rotation about the longitudinal axis.

As can be seen in FIG. 6, such an approach to guiding movement of the plunger assembly 604 not only allows for repeated movement with a high degree of consistency, but also avoids any friction from the plunger assembly 604 contacting the internal wall of the stator assembly 606. This friction can lead to poor and/or unreliable performance, and therefore avoiding this friction is important.

### Packaging and Internal Environment

Embodiments of the electromechanical actuator may benefit from being hermetically sealed to prevent ingress or egress of fluids (e.g., gasses and liquids) from the ambient environment into the chamber of the stator assembly or from the chamber of the stator assembly to the ambient environment.

In addition to being hermetically sealed, embodiments of the electromechanical actuator could be evacuated or have an insulating fluid deposited or injected therein. For example, the chamber defined within the stator assembly may be filled with a chemically inert, electrically insulating gas that is either above one atmosphere in pressure or below one atmosphere in pressure, or the chamber may be filled with a chemically inert, electrically insulating liquid that is either above one atmosphere in pressure or below one atmosphere in pressure. If used in an electromechanical relay, the chamber may be filled with the insulating fluid to provide sufficient dielectric standoff for a given stroke length of the plunger assembly. Having an atmospheric pressure in excess of one atmosphere will also result in a pressure bias being applied across any leakage paths through the hermetic envelope, thereby inhibiting or preventing ingress of atmosphere into the chamber. Liquids in the chamber may be electrically insulating or conductive depending on the application. A liquid may serve as a means of transmitting hydraulic force, or to provide dielectric breakdown resistance.

Generally, the insulating fluid is a chemically inert, electrically insulating gas that is comprised entirely or primarily of nitrogen. However, nitrogen could be mixed with one or more other electrically insulating gasses, for example, to improve arc resistance (as may be useful for an electromechanical relay). Other fluids could be used, however. For example, the insulating fluid may be another chemically inert, electrically insulating gas such as argon, or the insulating fluid may be a chemically inert, electrically insulating liquid such as hexamethyldisiloxane or octamethyltrisiloxane, which are low molecular weight, low viscosity silicones.

### Design Selection

Because the actuation force is proportional to acceleration, the total initial force at the beginning of a “stroke” disproportionately determines the time required to switch from one state to another state. Note that the total initial force can be broadly characterized by the sum of the latching force, actuation force, and flexure force. To maximize the force at the beginning of a “stroke,” the flexure can be used like a spring to offset the latching force. With the latching force partially, if not entirely, offset, the total initial force can instead be characterized by the sum of the actuation force and flexure force.

### Approaches to Designing and Manufacturing Electromechanical Actuators

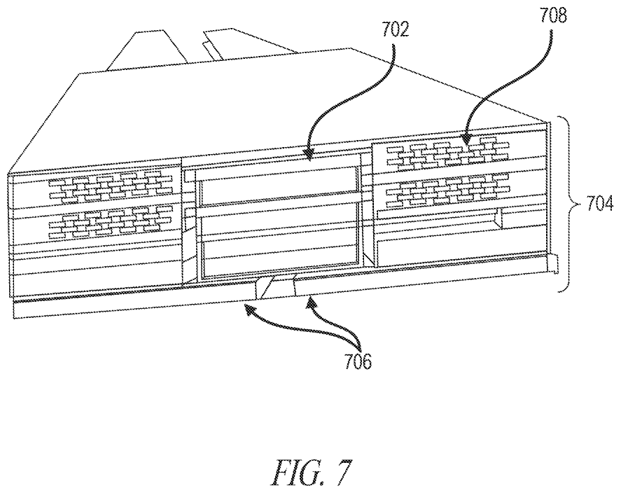

To design an electromechanical actuator in accordance with the embodiments disclosed herein, it is easiest to consider the electromechanical actuator as a combination of two components, namely, (i) a stator assembly that has a chamber partially defined therethrough along a central longitudinal axis and (ii) a plunger assembly that is situated in the chamber of the stator assembly and, in operation, moves along the central longitudinal axis between a first position and a second position. At a high level, the stator assembly includes two subcomponents, namely, (i) a contact assembly and (ii) a drive electromagnetics assembly. FIG. 7 includes a diagrammatic illustration of the plunger assembly 702 and stator assembly 708 of the stator assembly 704. As discussed above, the stator assembly 708 facilitates actuation of the plunger assembly 702 by generating magnetic fields when current is applied thereto. Actuation of the plunger assembly 702 results in its bottommost surface either engaging or disengaging the load-stops 706.

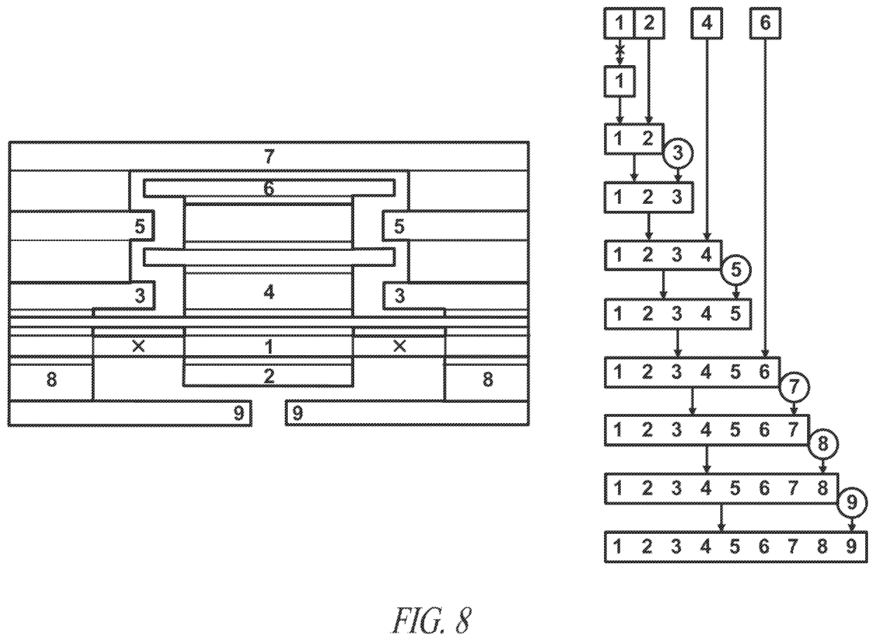

Fabrication of an electromechanical actuator requires the separate fabrication of its subcomponents. FIG. 8 includes an illustration of a set of steps that could be used to assemble the relay 200 as a collection of layers. Note that, for convenience, reference may be made to components discussed with reference to FIG. 2A. The order of assembly is important as the flexure layer—represented by flexure regions 208, 222 that are part of the same flexure—is included in both subassemblies. Furthermore, the interlocking aspect of the ferromagnetic layers requires the plunger assembly to be assembled in place as the plunger assembly 234 cannot be inserted through the opening in the middle ferromagnetic layer 214 after the plunger assembly 234 has been assembled. For the purpose of illustration, one possible order of assembly as illustrated in FIG. 8 is as follows:
Step 1: Start with spacer 1 that is rigidly connected between the plunger assembly 234 and stator assembly 232 by removable tabs marked with ‘x.’
Step 2: Load 2 is laminated to the spacer 1.
Step 3: Bottom ferromagnetic layer 210 is laminated to the assembly produced in Step 2.
Step 4: Spacer 224 of the plunger assembly 234, bottom ferromagnetic plate 226, and magnet 228 are laminated into the opening left inside of the bottom ferromagnetic layer 210.
Step 5: First set of coils 212A-B and middle ferromagnetic layer 214 are laminated to the assembly produced in Step 4.
Step 6: Top Ferromagnetic plate 230 is laminated to the top of the magnet 228.
Step 7: Second set of coils 212C-D and top ferromagnetic layer 216 are laminated to the top of the assembly produced in Step 6.
Step 8: Spacer layer 206 is laminated to the bottom of the assembly produced in Step 7. Then, the tabs (x) applied in Step 1 are removed to free the motion of the plunger assembly 234 as constrained by the flexure—collectively represented by 208 and 222.
Step 9: Assembly produced in Step 8 is placed atop the load-stops 204A-B. The load-stops 204A-B may be laminated or clamped in place below the assembly.

Those skilled in the art will recognize that other orders of assembly are possible and, in some embodiments, may be desirable based on the speed or precision with which the electromechanical actuator 200 is to be assembled.

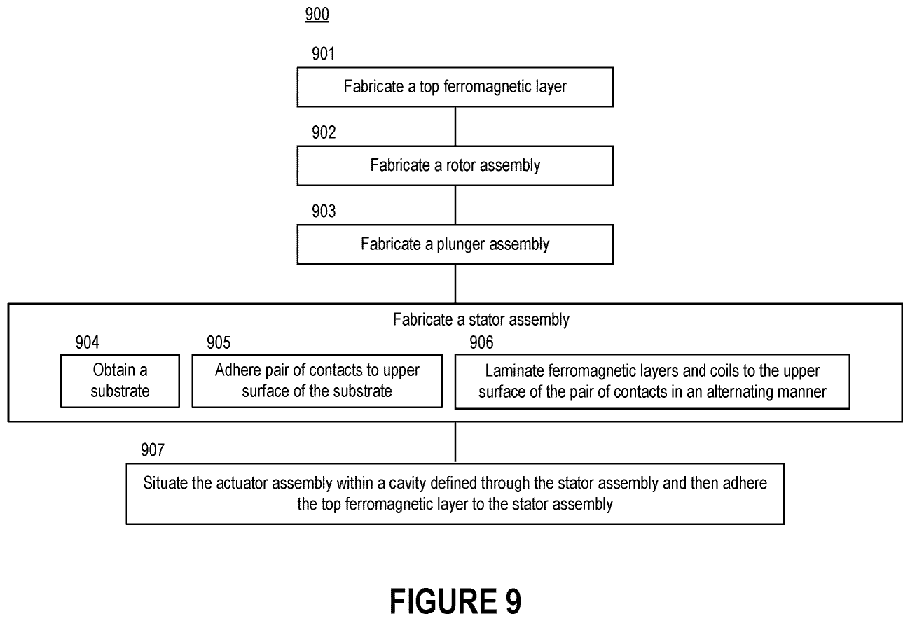

FIG. 9 includes a high-level diagram of a process 900 for fabricating an electromechanical actuator. Again, for convenience, reference may be made to components discussed with reference to FIG. 2A. However, FIG. 9 is specific to the design of an electromechanical actuator that does not include a flexure connecting the stator assembly and plunger assembly. Initially, a manufacturer can fabricate a top ferromagnetic layer (step 901), for example, by cutting a single layer from a piece of ferromagnetic material (e.g., steel). Then, the manufacturer can fabricate a plunger (step 902). For example, the manufacturer may create or acquire a permanent magnet and then layer ferromagnetic plates along its top and bottom poles. These ferromagnetic plates may be called the “top ferromagnetic plate” and “bottom ferromagnetic plate,” respectively. Thereafter, the manufacturer can fabricate the plunger assembly (step 903) by laminating, adhering, or otherwise connecting a spacer and load to the bottom ferromagnetic plate. Note that additional layers could be included in the plunger assembly.

To fabricate the stator assembly, the manufacturer can obtain a substrate (step 904), adhere the component with which the load interacts to the upper surface of the substrate (step 905), and then laminate ferromagnetic layers and coils to the upper surface of the pair of contacts in an alternating manner (step 906). Generally, the ferromagnetic layers and coils are laminated such that the resulting electromechanical actuator includes a trinity of ferromagnetic layers with one or more coils situated between the first and second ferromagnetic layers and another one or more coils situated between the second and third ferromagnetic layers. In some embodiments the lowermost ferromagnetic layer is laminated directly adjacent to the pair of contacts, while in other embodiments there are one or more intervening layers as shown in FIG. 2A.

To create the electromechanical actuator, the manufacturer can situate the plunger assembly within a cavity defined through the stator assembly and then adhere the top ferromagnetic layer to the stator assembly (step 907). Adhering the top ferromagnetic layer to the stator assembly causes a fully enclosed chamber to be defined inside the stator assembly. As discussed above, in operation, the plunger assembly is able to move between different positions inside the fully enclosed chamber.

### Remarks

The foregoing description of various embodiments of the claimed subject matter has been provided for the purposes of illustration and description. It is not intended to be exhaustive or to limit the claimed subject matter to the precise forms disclosed. Many modifications and variations will be apparent to one skilled in the art. Embodiments were chosen and described in order to best describe the principles of the invention and its practical applications, thereby enabling those skilled in the relevant art to understand the claimed subject matter, the various embodiments, and the various modifications that are suited to the particular uses contemplated.

Although the Detailed Description describes certain embodiments and the best mode contemplated, the technology can be practiced in many ways no matter how detailed the Detailed Description appears. Embodiments may vary considerably in their implementation details, while still being encompassed by the specification. Particular terminology used when describing certain features or aspects of various embodiments should not be taken to imply that the terminology is being redefined herein to be restricted to any specific characteristics, features, or aspects of the technology with which that terminology is associated. In general, the terms used in the following claims should not be construed to limit the technology to the specific embodiments disclosed in the specification, unless those terms are explicitly defined herein. Accordingly, the actual scope of the technology encompasses not only the disclosed embodiments, but also all equivalent ways of practicing or implementing the embodiments.

The language used in the specification has been principally selected for readability and instructional purposes. It may not have been selected to delineate or circumscribe the subject matter. It is therefore intended that the scope of the technology be limited not by this Detailed Description, but rather by any claims that issue on an application based hereon. Accordingly, the disclosure of various embodiments is intended to be illustrative, but not limiting, of the scope of the technology as set forth in the following claims.

What is claimed is:

1. An electromechanical actuator comprising:
a stator assembly that has a chamber partially defined therethrough along a central longitudinal axis,
wherein the stator assembly includes
a trinity of ferromagnetic layers with coils situated therebetween, such that (i) at least one coil is situated between a first ferromagnetic layer and a second ferromagnetic layer of the trinity of ferromagnetic layers and (ii) at least one coil is situated between the second ferromagnetic layer and a third ferromagnetic layer of the trinity of ferromagnetic layers, and
a first portion of a flexure; and
a plunger assembly that is situated in the chamber of the stator assembly and, in operation, moves along the central longitudinal axis between a first position and a second position,
wherein the plunger assembly includes
a plunger that includes a magnet, and
a second portion of the flexure;
wherein to move the plunger assembly between the first and second positions, current is applied to the coils; and
wherein movement of the plunger assembly is constrained by the flexure, as the second portion is configured to move with the plunger assembly while the first portion is configured to remain in a fixed position with the stator assembly.

2. The electromechanical actuator of claim 1, wherein the flexure flexibly connects the stator assembly and the plunger assembly together, such that the plunger assembly takes the same path through the chamber during each actuation between the first and second positions.

3. The electromechanical actuator of claim 1, wherein the flexure is designed to suspend the plunger assembly in the chamber, such that friction is largely or entirely eliminated between the plunger assembly and the stator assembly.

4. The electromechanical actuator of claim 1, wherein the flexure is comprised of metal, metal alloy, or polymer.

5. The electromechanical actuator of claim 1, wherein the flexure is designed to permit vertical displacement between 0 and 25 microns, between 25 and 100 microns, between 100 and 150 microns, between 150 and 200 microns, between 200 and 250 microns, or greater than 250 microns.

6. The electromechanical actuator of claim 1, wherein the flexure is in the form of a disk with a circular portion that is representative of the second portion and an annular portion that is representative of the first portion, and wherein the circular portion is connected to the annular portion by multiple interconnecting segments that are configured to flex.

7. The electromechanical actuator of claim 1, wherein the flexure is designed to provide a desired axial force when the actuator is latched, such that the axial force provided by the flexure counters the latching force to enable and support faster movement of a rotor when current is applied to the coils.

8. An electromechanical actuator, the actuator comprising:
a first assembly, wherein the first assembly comprises a ferromagnetic layer and a coil;
a second assembly, wherein the second assembly comprises a ferromagnetic plate and a permanent magnet, and wherein the ferromagnetic plate partially overlaps with the ferromagnetic layer; and
a flexure connecting the first assembly to the second assembly,
wherein the electromechanical actuator is characterized by a first position, wherein the first position is a stable state of the second assembly relative to the first assembly involving a first magnetic force resulting from a magnetic flux from the permanent magnet through the partial overlap between the ferromagnetic layer and the ferromagnetic plate.

9. The actuator of claim 8, wherein the first position corresponds to a magnetically latched position at an end of travel of the second assembly.

10. The actuator of claim 8, wherein the ferromagnetic plate is in contact with the ferromagnetic layer.

11. The actuator of claim 8, wherein the first position corresponds to an equilibrium involving the first magnetic force and a flexure force.

12. The actuator of claim 8, wherein the first assembly comprises a plurality of ferromagnetic layers, wherein any two adjacent ferromagnetic layers are separated by one or more coils.

13. The actuator of claim 8, wherein the first assembly comprises a plurality of ferromagnetic layers, wherein any two adjacent ferromagnetic layers are separated by one or more coils, wherein the second assembly comprises a plurality of ferromagnetic plates, wherein any two adjacent ferromagnetic plates are separated by one or more permanent magnets, the plurality of ferromagnetic layers and the plurality of ferromagnetic plates being alternatingly overlapped along an axis of travel of the second assembly.

14. The actuator of claim 8, wherein the first assembly comprises a plurality of ferromagnetic layers, wherein any two adjacent ferromagnetic layers are separated by one or more coils, the ferromagnetic plate is the only ferromagnetic plate in the second assembly, wherein the ferromagnetic plate and the plurality of ferromagnetic layers are alternatingly overlapped along an axis of travel of the second assembly.

15. The actuator of claim 8, wherein the second assembly comprises a plurality of permanent magnets, wherein the plurality of permanent magnets is arranged with alternating polarizations.

16. The actuator of claim 8, wherein the second assembly is configured to move along an axis of travel within the first assembly.
